(19) United States
(12) Patent Application Publication
(10) Pub. No.: US 2024/0329549 A1
(43) Pub. Date: Oct. 3, 2024

(54) EXPOSURE APPARATUS

(71) Applicant: Ushio Denki Kabushiki Kaisha, Tokyo (JP)

(72) Inventors: Naoya SOHARA, Tokyo (JP); Hiroyuki SUZUKI, Tokyo (JP)

(73) Assignee: Ushio Denki Kabushiki Kaisha, Tokyo (JP)

(21) Appl. No.: 18/604,063

(22) Filed: Mar. 13, 2024

(30) Foreign Application Priority Data
Mar. 29, 2023 (JP) 2023-053552

(51) Int. Cl. G03F 9/00; G03F 7/00

(52) U.S. Cl. CPC G03F 9/7096; G03F 7/70716; G03F 9/7049; G03F 9/7088

(57) ABSTRACT

An exposure apparatus includes: a light-emission unit that emits exposure light; a mask stage that holds an exposure mask; a workpiece stage that holds a workpiece; a projection optical system that irradiates the workpiece held by the workpiece stage with the exposure light emitted from the light-emission unit through the exposure mask; a reflective member disposed in an irradiation region for the exposure light applied from the projection optical system in a step of detecting a mask mark of the exposure mask; an alignment microscope that is disposed in an optical path of the exposure light applied to the mask mark and captures an image of the mask mark on the basis of reflected light reflected by the reflective member in the detection step; and a moving mechanism that moves the reflective member from a position deviated from the irradiation region to the irradiation region in the detection step.

### CROSS REFERENCE TO RELATED APPLICATIONS

This application claims the benefit of Japanese Priority Patent Application JP 2023-053552 filed Mar. 29, 2023, the entire contents of which are incorporated herein by reference.

### BACKGROUND

The present invention relates to an exposure apparatus.

Exposure apparatuses are used in the step of manufacturing a pattern of a semiconductor element, a printed-circuit board, a liquid crystal substrate, or the like by photolithography. The exposure apparatus performs alignment such that a mask (reticle) on which a pattern is formed and a workpiece to which the pattern is to be transferred have a predetermined positional relationship. Subsequently, the exposure apparatus irradiates, by a projection optical system, the workpiece with exposure light with which the mask is irradiated, so that the mask pattern is transferred (exposed) to the workpiece.

Japanese Patent Application Laid-open No. Hei 08-233529 discloses an alignment unit (also referred to as alignment microscope) for performing alignment of a mask and a workpiece in an exposure apparatus as described above. A mask mark formed on the mask and a workpiece mark formed on the workpiece are imaged by the alignment unit. Positional coordinates of the mask mark and the workpiece mark are calculated on the basis of the captured images of the mask mark and the workpiece mark. At least one of the mask or the workpiece is moved such that the positions of both the mask and the workpiece have a positional relationship set in advance.

In the exposure apparatus disclosed in Japanese Patent Application Laid-open No. Hei 08-233529, a reflective member that is a total reflection mirror or a half mirror is embedded into the substantially entire surface of the workpiece stage. A mask mark projected onto the reflective member is imaged by the alignment unit in the step of detecting a mask mark.

### SUMMARY

In recent years, the miniaturization of a wiring pattern or the like has become increasingly advanced, and a further improvement in exposure accuracy has been expected.

In view of the circumstances as described above, it is desirable to provide an exposure apparatus capable of improving alignment accuracy of a mask and a workpiece and achieving high exposure accuracy.

According to an embodiment of the present invention, there is provided an exposure apparatus including a light-emission unit, a mask stage, a workpiece stage, a projection optical system, a reflective member, an alignment microscope, and a moving mechanism.

The light-emission unit emits exposure light.

The mask stage holds an exposure mask.

The workpiece stage holds a workpiece.

The projection optical system irradiates the workpiece held by the workpiece stage with the exposure light, the exposure light being emitted from the light-emission unit and passing through the exposure mask.

The reflective member is disposed in an irradiation region for the exposure light applied from the projection optical system in a step of detecting a mask mark, the mask mark being an alignment mark of the exposure mask.

The alignment microscope is disposed in an optical path of the exposure light applied to the mask mark and captures an image of the mask mark on the basis of reflected light that is reflected by the reflective member in the step of detecting the mask mark.

The moving mechanism moves the reflective member from a position deviated from the irradiation region to the irradiation region in the step of detecting the mask mark.

In this exposure apparatus, the reflective member is moved from a position deviated from the irradiation region for the exposure light to the irradiation region in the step of detecting the mask mark. This makes it possible to improve alignment accuracy of the mask and the workpiece and to achieve high exposure accuracy.

The workpiece stage may include a placement surface on which the workpiece is placed. In this case, the moving mechanism may move the workpiece stage such that the placement surface is deviated from the irradiation region and may move the reflective member to the irradiation region in the step of detecting the mask mark.

The moving mechanism may insert the reflective member between the workpiece stage and the alignment microscope to move the reflective member to the irradiation region in the step of detecting the mask mark.

The reflective member may be formed to have a size equal to or larger than a size of the irradiation region, and may reflect a whole of the exposure light applied from the projection optical system.

The reflective member may be connected to a position different from the placement surface of the workpiece stage. In this case, the moving mechanism may move the workpiece stage to move the reflective member to the irradiation region.

The reflective member may be connected to the workpiece stage such that a height position of a surface of the reflective member is equal to a height position of a surface of the workpiece placed on the placement surface.

The exposure apparatus may further include a moving stage that holds the reflective member. In this case, the moving mechanism may move each of the workpiece stage and the moving stage to move the reflective member to the irradiation region.

The moving mechanism may move each of the workpiece stage and the moving stage along an identical plane. In this case, the reflective member may be held by the moving stage such that a height position of a surface of the reflective member is equal to a height position of a surface of the workpiece placed on the placement surface.

The reflective member may be formed to have a size that covers a whole of the workpiece and may block the exposure light applied to the workpiece in the step of detecting the mask mark.

As described above, according to the present invention, it is possible to improve alignment accuracy of a mask and a workpiece and achieve high exposure accuracy. Note that the effects described herein are not necessarily limited and may be any effect described in the present disclosure.

These and other objects, features and advantages of the present disclosure will become more apparent in light of the following detailed description of best mode embodiments thereof, as illustrated in the accompanying drawings.

### BRIEF DESCRIPTION OF DRAWINGS

FIG. 1 is a schematic diagram showing a basic configuration example of an exposure apparatus according to a first embodiment of the present invention;

FIG. 2 is a schematic diagram for describing an operation example of detecting an alignment mark using an alignment microscope (step of detecting mask mark);

FIG. 3 is a schematic diagram for describing an operation example of detecting an alignment mark using the alignment microscope (step of detecting workpiece mark);

FIG. 4 is a schematic diagram showing the step of detecting a mask mark of an exposure apparatus according to a second embodiment;

FIG. 5 is a schematic diagram showing the step of detecting a workpiece mark of the exposure apparatus according to the second embodiment;

FIG. 6 is a schematic diagram showing the step of detecting a mask mark of an exposure apparatus according to a third embodiment; and

FIG. 7 is a schematic diagram showing the step of detecting a workpiece mark of the exposure apparatus according to the third embodiment.

### DETAILED DESCRIPTION OF EMBODIMENTS

Hereinafter, embodiments according to the present invention will be described with reference to the drawings.

### First Embodiment

### Configuration of Exposure Apparatus

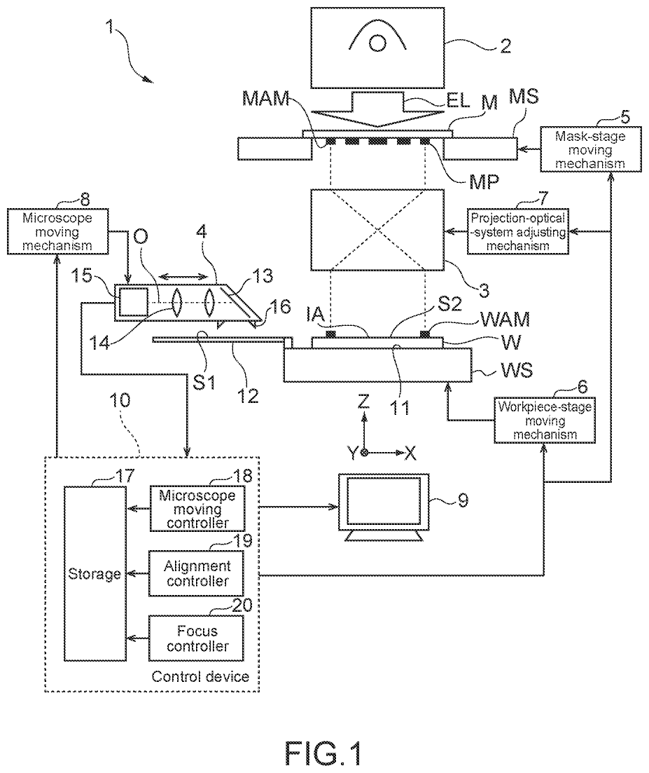

FIG. 1 is a schematic diagram showing a basic configuration example of an exposure apparatus according to a first embodiment of the present invention.

An exposure apparatus 1 includes a light-emission unit 2, a mask stage MS, a workpiece stage WS, a projection optical system 3, an alignment microscope 4, a mask-stage moving mechanism 5, a workpiece-stage moving mechanism 6, a projection-optical-system adjusting mechanism 7, a microscope moving mechanism 8, a monitor 9, and a control device 10.

Hereinafter, as shown in FIG. 1, an optical axis direction of the light-emission unit 2 (emission direction of exposure light EL) will be referred to as a Z direction, the positive side of the Z axis as an upper side, and the negative side thereof as a lower side. Further, a direction orthogonal to the Z direction and extending in the right and left of the figure will be referred to as an X direction, the positive side of the X axis as a right side, and the negative side thereof as a left side. Further, a depth direction orthogonal to the Z direction and the X direction and extending perpendicularly to the plane of the figure will be referred to as a Y direction, the positive side of the Y axis as a far side, and the negative side thereof as a near side. As a matter of course, for the application of the present technology, a direction in which the exposure apparatus 1 is disposed and the like are not limited.

The light-emission unit 2 emits exposure light EL toward the lower side. For example, a short-arc mercury lamp is used as the light-emission unit 2. For example, ultraviolet light including the wavelengths of 365 nm (i-line), 405 nm (h-line), 436 nm (g-line), and the like is emitted from the mercury lamp. As a matter of course, the present invention is not limited to such a configuration. A lamp that emits light in a wavelength band different from that of the ultraviolet light may be used. In addition, a solid-state light source such as a light-emitting diode (LED) or a laser diode (LD) may be used.

The mask stage MS is disposed below the light-emission unit 2. The mask stage MS holds an exposure mask (hereinafter, simply referred to as mask) M. In this embodiment, the mask M is disposed to be orthogonal to the optical axis direction of the light-emission unit 2 (Z direction). The mask M includes a predetermined mask pattern MP formed thereon. Further, the mask M includes an alignment mark (mask mark) MAM formed thereon. The mask mark MAM is also referred to as a mask/alignment mark.

The projection optical system 3 irradiates a workpiece W, which is held by the workpiece stage WS, with the exposure light EL emitted from the light-emission unit 2 and transmitted through the mask M. Thus, an image of the mask pattern MP formed on the mask M is projected onto the workpiece W. The projection optical system 3 is configured as an image-forming optical system including a projection lens. A specific configuration of the projection optical system 3 is not limited, and any configuration may be employed.

The workpiece stage WS holds the workpiece W. In this embodiment, the workpiece W is disposed to be orthogonal to the optical axis direction of the light-emission unit 2 (Z direction).

The workpiece stage WS includes a placement surface (placement region) 11 on which the workpiece W is placed. The placement surface 11 includes a plurality of vacuum-suction holes formed therein, and the workpiece W is held by vacuum suction. Note that a specific configuration or method for holding the workpiece W is not limited and may be discretionally designed.

The mask-stage moving mechanism 5 linearly moves (performs linear motion of) the mask stage MS in each of the horizontal direction (X direction), the depth direction (Y direction), and the vertical direction (Z direction). Further, the mask-stage moving mechanism 5 rotates the mask stage MS with the vertical direction (Z direction) being used as a rotation-axis direction. Furthermore, the mask-stage moving mechanism 5 tilts (inclines) the mask stage MS relative to the optical axis direction of the light-emission unit 2 (Z direction).

The workpiece-stage moving mechanism 6 linearly moves the workpiece stage WS in each of the horizontal direction (X direction), the depth direction (Y direction), and the vertical direction (Z direction). Further, the workpiece-stage moving mechanism 6 rotates the workpiece stage WS with the vertical direction (Z direction) being used as a rotation-axis direction. Furthermore, the workpiece-stage moving mechanism 6 tilts the workpiece stage WS relative to the optical axis direction of the light-emission unit 2 (Z direction).

Each of the mask-stage moving mechanism 5 and the workpiece-stage moving mechanism 6 is driven, so that a relative position of the workpiece W relative to the mask M can be varied.

Specific configurations of the mask-stage moving mechanism 5 and the workpiece-stage moving mechanism 6 are not limited. For example, any moving mechanism such as a linear stage using a stepping motor or the like, any rotary mechanism using a gear mechanism or the like, and other mechanisms may be used.

For example, the workpiece stage WS is disposed on a surface plate (platen) and is moved in a state of being magnetically elevated by a linear motor. Such a configuration can also be employed. In this case, the whole including the surface plate will be referred to as a workpiece stage, and a workpiece stage WS holding the workpiece W can also be referred to as a mobile object.

Further, as the configurations of the mask-stage moving mechanism 5 and the workpiece-stage moving mechanism 6, any configuration capable of varying a relative position relationship of the workpiece stage WS relative to the mask stage MS can be employed.

For example, only the mask-stage moving mechanism 5 may be provided, and only the mask stage MS may be movable. Alternatively, only the workpiece-stage moving mechanism 6 may be provided, and only the workpiece stage WS may be movable. Further, regarding the movement in the horizontal direction (X direction), the depth direction (Y direction), and the vertical direction (Z direction), the mask-stage moving mechanism 5 moves the mask stage MS. Regarding the rotation with the vertical direction (Z direction) being used as a rotation-axis direction and regarding the tilt (inclination) relative to the optical axis direction (Z direction), the workpiece-stage moving mechanism 6 moves the workpiece stage WS. Such a configuration can also be employed.

The workpiece W includes an alignment mark (workpiece mark) WAM formed thereon. The workpiece mark WAM is also referred to as a workpiece/alignment mark.

In rotation directions in which the horizontal direction (X direction), the depth direction (Y direction), and the vertical direction (Z direction) are rotation-axis directions, it is desirable to form three or more mask marks MAM on the mask M in order to align the mask M and the workpiece W. The same number of workpiece marks WAM is formed on the workpiece W so as to correspond to the three or more mask marks MAM.

For example, it is assumed that a mask M having a rectangular shape as viewed from the vertical direction (Z direction) is used. In this case, for example, the mask marks MAM are formed at four corners of the mask M. Further, a substrate having a rectangular shape as viewed from the vertical direction (Z direction) is disposed as the workpiece W. The workpiece marks WAM are formed at four corners of the workpiece W so as to correspond to the mask marks MAM formed at the four corners of the mask M. As a matter of course, the present invention is not limited to such a configuration.

The mask mark MAM and the workpiece mark WAM corresponding to each other are formed to have a predetermined positional relationship if the mask M and the workpiece W have a desired positional relationship as viewed from the vertical direction (Z direction). In this embodiment, description will be given assuming that the mask mark MAM and the workpiece mark WAM corresponding to each other are located at the same position if the mask M and the workpiece W have a desired positional relationship. As a matter of course, the present invention is not limited to such a setting, and any positional relationship may be set as a predetermined positional relationship.

As shown in FIG. 1, a reflective member 12 is connected to and fixed at a left end portion of the workpiece stage WS. The reflective member 12 is connected to the workpiece stage WS such that a height position of an upper surface S1 of the reflective member 12 is equal to a height position of an upper surface S2 of the workpiece W placed on the placement surface 11. The reflective member 12 is moved integrally with the workpiece stage WS.

Note that, in the present disclosure, the concept of “equal” is the concept including “substantially equal” as will be described later. For example, the states included in a predetermined range (e.g., range of ±10%) with reference to “completely equal” are also included.

As the reflective member 12, for example, a total reflection mirror, a half mirror, or the like is used. In addition, any configuration may be employed as the reflective member 12 if the mask mark MAM projected onto the reflective member 12 can be imaged in the step of detecting the mask mark MAM to be described later.

Further, the reflective member 12 is configured to have a size equal to or larger than the size of an irradiation region IA for the exposure light EL transmitted through the mask M and radiated by the projection optical system 3 as viewed from above. Typically, the reflective member 12 is configured to have a size larger than the size of the irradiation region IA for the exposure light EL. In other words, the reflective member 12 is configured to have a size that covers the irradiation region IA for the exposure light EL. Note that the irradiation region IA for the exposure light EL is an exposure surface that can be exposed in the exposure step for the workpiece W.

It is assumed that the workpiece-stage moving mechanism 6 is driven, and the reflective member 12 connected to the workpiece stage WS is disposed at a position on the optical axis of the exposure light EL on the lower side of the projection optical system 3. When the exposure light EL is radiated in that state, the whole of the exposure light EL radiated by the projection optical system 3 is reflected by the reflective member 12.

Therefore, image light of the mask M is formed on the reflective member 12 and the whole image of the mask M appears on the reflective member 12. As a matter of course, an image of the mask mark MAM also appears on the reflective member 12.

The projection-optical-system adjusting mechanism 7 adjusts the projection optical system 3. For example, when the projection-optical-system adjusting mechanism 7 is driven, adjustment of a focus position, adjustment of an image-forming magnification, correction of distortion, and the like are performed. For example, adjustment of a position, processing, replacement, or the like of an optical element such as the projection lens included in the projection optical system 3 makes it possible to adjust the projection optical system 3. A specific configuration of the projection-optical-system adjusting mechanism 7 is not limited, and any configuration may be employed.

The microscope moving mechanism 8 linearly moves the alignment microscope 4 in each of the horizontal direction (X direction), the depth direction (Y direction), and the vertical direction (Z direction). Note that the microscope moving mechanism 8 may rotate the alignment microscope 4 with the vertical direction (Z direction) being used as a rotation-axis direction. Further, the microscope moving mechanism 8 may be capable of tilting the alignment microscope 4 relative to the optical axis direction of the light-emission unit 2 (Z direction).

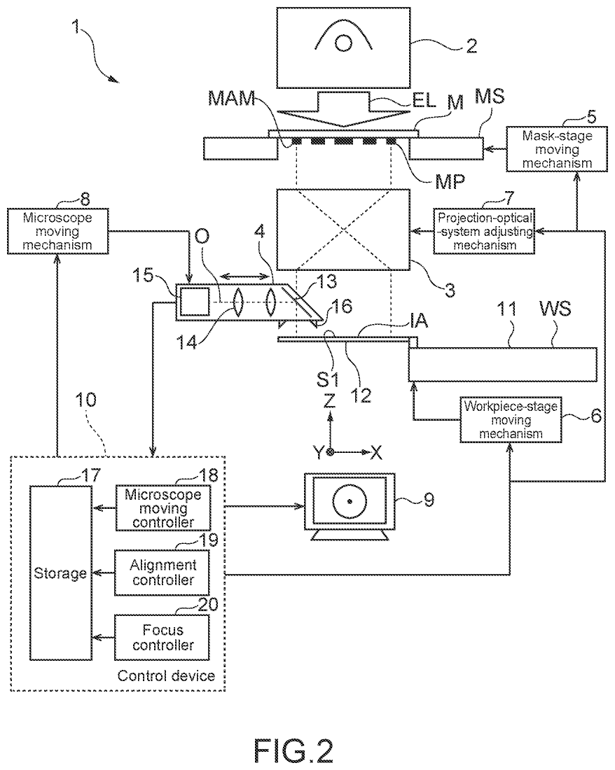

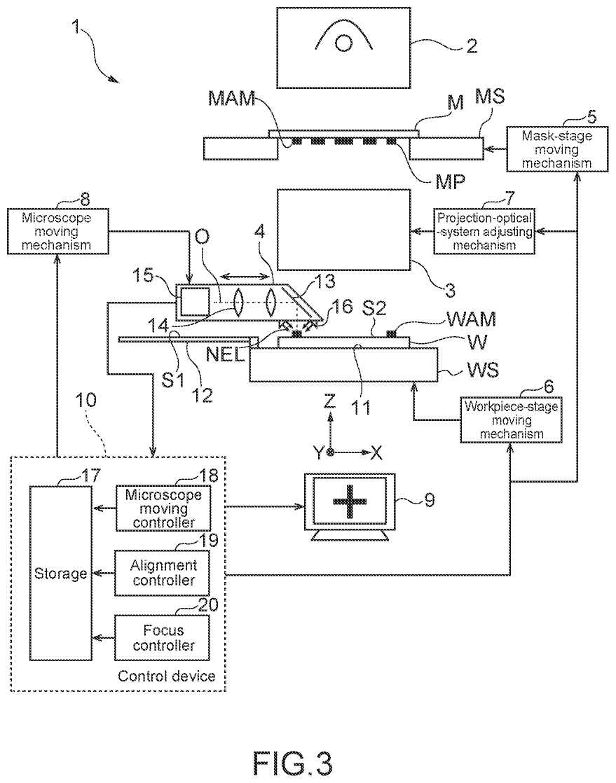

When the microscope moving mechanism 8 is driven, the alignment microscope 4 can be moved from an imaging position, which is between the projection optical system 3 and the workpiece stage WS (workpiece W) (see FIGS. 2 and 3), to a retracted position shown in FIG. 1.

If the alignment microscope 4 is movable between the imaging position and the retracted position, a movable direction may be limited. For example, a configuration that allows only a linear motion in each of the horizontal direction (X direction), the depth direction (Y direction), and the vertical direction (Z direction) may be employed. Alternatively, a configuration capable of moving only in the horizontal direction (X direction) may also be employed.

A specific configuration of the microscope moving mechanism 8 is not limited. For example, any moving mechanism such as a linear stage using a stepping motor or the like, any rotary mechanism using a gear mechanism or the like, and other mechanisms may be used.

The alignment microscope 4 is used for alignment of the mask M and the workpiece W. The alignment microscope 4 can capture an enlarged image of the mask mark MAM and an enlarged image of the workpiece mark WAM.

The alignment microscope 4 has a roughly columnar shape extending in one direction and incorporates a beam splitter 13, a lens system 14, and an optical sensor 15.

Inside the alignment microscope 4, the beam splitter 13, the lens system 14, and the optical sensor 15 are disposed with an imaging optical axis O of the optical sensor 15 being used as a reference.

As the beam splitter 13, any configuration capable of splitting incident light to emit the split light to the optical sensor 15 may be employed. For example, beam splitters having various configurations, such as a plate beam splitter, a pellicle beam splitter, and a cube beam splitter, may be used.

As the lens system 14, any configuration including an objective lens or the like may be employed. For example, if a cube beam splitter is used, an aberration correction lens may be disposed as the lens system 14.

In this embodiment, an imaging device (imaging unit) capable of capturing a two-dimensional image is used as the optical sensor 15. For example, a digital camera including an image sensor such as a charge-coupled device (CCD) sensor or a complementary metal-oxide semiconductor (CMOS) sensor can be used. The present invention is not limited to the above, and a digital camera using an image-forming lens such as a non-telecentric lens or a telecentric lens and the image sensor in combination may be used.

Further, an illumination unit 16 is disposed at a position on the lower side of the beam splitter 13 of the alignment microscope 4. The illumination unit 16 emits non-exposure light NEL (see FIG. 3) toward the lower side. For example, a ring lighting is used as the illumination unit 16, and visible light is emitted as the non-exposure light NEL. As a matter of course, the present invention is not limited to such a configuration, and a configuration in which a coaxial illumination method is performed may be employed.

The control device 10 controls an operation of each block of the exposure apparatus 1. The control device 10 includes hardware necessary for the computer, for example, a processor such as a central processing unit (CPU), a graphics processing unit (GPU), or a digital signal processor (DSP), a memory such as a read-only memory (ROM) or a random access memory (RAM), and a storage device such as a hard disk drive (HDD). In this embodiment, storage 17 is formed by a storage device such as a nonvolatile memory. In order to implement the storage 17, any non-transitory computer-readable storage medium may be used.

The processor of the control device 10 loads a program according to the present technology, which is stored in the storage 17 or the memory, to the RAM and executes the program, so that an alignment method and an exposure method including a focus control method according to the present technology are executed.

For example, any computer such as a personal computer (PC) can implement the control device 10. As a matter of course, hardware including a programmable logic device (PLD) such as a field-programmable gate array (FPGA), an application specific integrated circuit (ASIC), or the like may be used.

In this embodiment, the processor of the control device 10 executes the program according to the present technology, and thus a microscope moving controller 18, an alignment controller 19, and a focus controller 20 are implemented as functional blocks.

The microscope moving controller 18 controls the microscope moving mechanism 8 to move the alignment microscope 4. In the step of detecting the mask mark MAM and the step of detecting the workpiece mark WAM, the alignment microscope 4 is moved to the imaging position between the projection optical system 3 and the workpiece stage WS (workpiece W) (see FIGS. 2 and 3). In the exposure step for the workpiece W, the alignment microscope 4 is moved to the retracted position as shown in FIG. 1.

The alignment controller 19 detects each of a position of the mask mark MAM and a position of the workpiece mark WAM on the basis of an image of the mask mark MAM and an image of the workpiece mark WAM, which are captured by the optical sensor 15 of the alignment microscope 4.

Further, on the basis of the detected position of the mask mark MAM and the detected position of the workpiece mark WAM, the alignment controller 19 controls the mask-stage moving mechanism 5 and the workpiece-stage moving mechanism 6 to perform alignment such that the mask M and the workpiece W have a desired positional relationship. Specifically, the alignment controller 19 controls the mask-stage moving mechanism 5 and the workpiece-stage moving mechanism 6 such that the mask mark MAM and the workpiece mark WAM are located at the same position, that is, have a predetermined positional relationship. This makes it possible to align the mask M and the workpiece W.

The focus controller 20 controls the focus of the mask pattern MP, which is projected (image-formed) onto the workpiece W. Specifically, the focus controller 20 controls the projection-optical-system adjusting mechanism 7, the mask-stage moving mechanism 5, and the workpiece-stage moving mechanism 6 such that the workpiece W is disposed at a focus position of the projection optical system 3.

In this embodiment, as the focus control, the focus position of the projection optical system 3 is adjusted by driving the projection-optical-system adjusting mechanism 7, the position of the mask stage MS in the vertical direction (Z direction) is adjusted by driving the mask-stage moving mechanism 5, and the position of the workpiece stage WS in the vertical direction (Z direction) is adjusted by driving the workpiece-stage moving mechanism 6. As a matter of course, the present invention is not limited to such control, an any focus control may be executed.

In addition, the functional blocks that execute various types of control regarding exposure are established in the control device 10, though not illustrated. Further, in order to implement the functional blocks, dedicated hardware such as an integrated circuit (IC) may be appropriately used.

When the alignment of the mask M and the workpiece W and the focus control are completed, the exposure step for the workpiece W is started, and the exposure light EL is emitted from the light-emission unit 2. The workpiece W coated with a resist is irradiated with the exposure light EL, which is emitted from the light-emission unit 2, through the mask M on which the mask pattern MP is formed and the projection optical system 3. Thus, the mask pattern MP is projected onto the workpiece W and exposed.

FIGS. 2 and 3 are schematic diagrams for describing an operation example of detecting an alignment mark (mask mark MAM/workpiece mark WAM) using the alignment microscope 4. FIG. 2 is a schematic diagram showing the step of detecting the mask mark MAM. FIG. 3 is a schematic diagram showing the step of detecting the workpiece mark WAM.

First, as shown in FIG. 2, the mask M is disposed on the mask stage MS. For example, the control device 10 drives a robot arm or the like (illustration omitted) such that the mask M is disposed at a reference position before alignment. As a matter of course, the mask M may be disposed by an operator.

Further, in the step of detecting the mask mark MAM, the reflective member 12 is moved to the irradiation region IA from a position outside the irradiation region IA for the exposure light EL with which the projection optical system 3 is irradiated.

In this embodiment, when the workpiece-stage moving mechanism 6 is driven, the workpiece stage WS is moved such that the placement surface 11 is moved outside the irradiation region IA for the exposure light EL, and thus the reflective member 12 is moved to the irradiation region IA for the exposure light EL. The reflective member 12 is connected to a position different from the placement surface 11 of the workpiece stage WS. The workpiece-stage moving mechanism 6 moves the workpiece stage WS and thus moves the reflective member 12 to the irradiation region IA for the exposure light EL.

As shown in FIG. 2, the alignment microscope 4 is moved to an imaging position of the alignment mark. The imaging position of the alignment mark is set between the projection optical system 3 and the workpiece stage WS (workpiece W).

The imaging position of the alignment mark is set to be a position at which the beam splitter 13 of the alignment microscope 4 is disposed in the optical path of the exposure light EL with which the mask mark MAM has been irradiated. In other words, the imaging position of the alignment mark is set to be a position at which the exposure light EL with which the mask mark MAM has been irradiated enters the beam splitter 13 of the alignment microscope 4.

As shown in FIG. 2, in this embodiment, the beam splitter 13 is disposed at an intersection angle of 45 degrees relative to the optical path of the exposure light EL, the optical path extending in the vertical direction (Z direction). Specifically, the beam splitter 13 is disposed so as to be parallel to a direction of a slant angle of 45 degrees from the upper left to the lower right.

When the exposure light EL is emitted from the light-emission unit 2, the exposure light EL with which the mask mark MAM is irradiated enters the beam splitter 13 from the upper side through the projection optical system 3. The exposure light EL passing through the beam splitter 13 and traveling toward the lower side is reflected toward the upper side by the reflective member 12.

The exposure light EL reflected toward the upper side is reflected by the beam splitter 13, travels toward the left side along the horizontal direction (X direction), and enters the optical sensor 15. Thus, an image of the mask mark MAM is captured by the optical sensor 15.

As described above, in this embodiment, the alignment microscope 4 is disposed in the optical path of the exposure light EL with which the mask mark MAM is irradiated, and the image of the mask mark MAM is captured on the basis of the reflected light reflected by the reflective member 12.

The alignment controller 19 of the control device 10 detects the position of the mask mark MAM on the basis of the image of the mask mark MAM captured by the optical sensor 15 of the alignment microscope 4. Further, the alignment controller 19 can also take in the image of the mask mark MAM captured by the optical sensor 15, and cause the monitor 9 to display the image. An operator can confirm the detection of the mask mark MAM by visually recognizing the image of the mask mark MAM displayed on the monitor 9.

In this embodiment, the alignment controller 19 detects coordinates of the central position of the mask mark MAM as a position of the mask mark MAM. In the example shown in FIG. 2, a circular mask mark MAM is detected, and the coordinates of the central position thereof are calculated. As a matter of course, the shape of the mask mark MAM, and a position of the mask mark MAM to be detected as the position of the mask mark MAM are not limited and may be discretionally set.

In order to detect the position of the mask mark MAM, for example, any image recognition technology such as image size conversion, character recognition, shape recognition, matching processing using a model image of an object, edge detection, or projection transformation may be used. Further, any machine learning algorithm using, for example, a deep neural network (DNN), a recurrent neural network (RNN), or a convolutional neural network (CNN) may be used. Note that a machine learning algorithm may be applied to any processing in the present disclosure.

The image of the mask mark MAM acquired by the alignment controller 19, and the position of the mask mark MAM detected by the alignment controller 19 (coordinates of central position) are stored in the storage 17.

As shown in FIG. 3, the emission of the exposure light EL by the light-emission unit 2 is stopped in the step of detecting the workpiece mark WAM. The workpiece W is then placed on the placement surface 11 of the workpiece stage WS. The workpiece stage WS is moved such that the workpiece W is disposed on the lower side of the projection optical system 3.

For example, the control device 10 drives a robot arm or the like (illustration omitted), and thus the workpiece W is disposed on the placement surface 11. As a matter of course, the workpiece W may be disposed by the operator.

The alignment microscope 4 is not moved and remains disposed at the imaging position of the alignment mark. The illumination unit 16 of the alignment microscope 4 then irradiates the workpiece mark WAM with the non-exposure light NEL. The non-exposure light NEL with which the workpiece mark WAM is irradiated is reflected by the workpiece mark WAM and enters the beam splitter 13 disposed above the workpiece mark WAM.

The non-exposure light NEL that is incident on the beam splitter 13 is reflected, travels toward the left side along the horizontal direction (X direction), and enters the optical sensor 15. Thus, an image of the workpiece mark WAM is captured by the optical sensor 15.

The alignment controller 19 of the control device 10 detects the position of the workpiece mark WAM on the basis of the image of the workpiece mark WAM captured by the optical sensor 15 of the alignment microscope 4. Further, the alignment controller 19 can also take in the image of the workpiece mark WAM captured by the optical sensor 15, and cause the monitor 9 to display the image. Thus, the operator can confirm the detection of the workpiece mark WAM by visually recognizing the image of the workpiece mark WAM displayed on the monitor 9.

As shown in FIG. 3, in this embodiment, coordinates of the central position of the workpiece mark WAM having a cross shape are calculated as a position of the workpiece mark WAM. As a matter of course, the shape of the workpiece mark WAM, and a position of the workpiece mark WAM to be detected as the position of the workpiece mark WAM are not limited and may be discretionally set. For example, the workpiece mark WAM may be configured with the same shape as that of the mask mark MAM.

The image of the workpiece mark WAM acquired by the alignment controller 19, and the position of the workpiece mark WAM detected by the alignment controller 19 (coordinates of central position) are stored in the storage 17.

The alignment controller 19 controls the workpiece stage WS such that the positional relationship between the mask mark MAM and the workpiece mark WAM is a predetermined positional relationship. In this embodiment, the mask-stage moving mechanism 5 and the workpiece-stage moving mechanism 6 are driven such that the position of the mask mark MAM (coordinates of central position) and the position of the workpiece mark WAM (coordinates of central position) coincide with each other, and a relative position of the workpiece W relative to the mask M is controlled.

FIGS. 1 to 3 show only the single alignment microscope 4 disposed for a set of the mask mark MAM and the workpiece mark WAM corresponding to each other. If a plurality of sets of the mask mark MAM and the workpiece mark WAM are formed, alignment is performed using the alignment microscopes 4 for the plurality of sets of the mask mark MAM and the workpiece mark WAM corresponding to each other.

For example, a single alignment microscope 4 is disposed for each set of the mask mark MAM and the workpiece mark WAM corresponding to each other, and an image of the mask mark MAM and an image of the workpiece mark WAM are captured. The present invention is not limited to the above, and an image of the mask mark MAM and an image of the workpiece mark WAM may be sequentially captured by a smaller number of alignment microscopes 4, e.g., one alignment microscope 4, than the number of sets of the mask mark MAM and the workpiece mark WAM.

For example, the mask marks MAM are formed at the four corners of the rectangular mask M, and the workpiece marks WAM are formed at the four corners of the workpiece W formed of a rectangular substrate. In this case, four alignment microscopes 4 are respectively disposed at imaging positions of the alignment marks, the imaging positions being a position in the optical path of the exposure light EL with which each mask mark MAM is irradiated and a position in the optical path of the non-exposure light NEL with which each workpiece mark WAM corresponding to the mask mark MAM is irradiated.

The alignment controller 19 of the control device 10 detects the positions of the four mask marks MAM and the positions of the four workpiece marks WAM. The mask-stage moving mechanism 5 and the workpiece-stage moving mechanism 6 are then controlled such that the four sets of the mask mark MAM and the workpiece mark WAM corresponding to each other respectively have predetermined positional relationships. This makes it possible to perform alignment of the mask M and the workpiece W in the rotation directions with the horizontal direction (X direction), the depth direction (Y direction), and the vertical direction (Z direction) being used as rotation-axis directions.

When the alignment of the mask M and the workpiece W is completed, the alignment microscope 4 is retracted to the retracted position shown in FIG. 1. As a matter of course, the alignment microscope 4 may be retracted to the retracted position at other timings such as a timing at which the capturing of the image of the mask mark MAM and the image of the workpiece mark WAM is completed, and a timing at which the detection of the position of the mask mark MAM and the position of the workpiece mark WAM by the alignment controller 19 is completed.

In such a manner, in this embodiment, in the step of detecting the mask mark MAM, the reflective member 12 having a size equal to or larger than the size of the irradiation region IA is disposed in the irradiation region IA for the exposure light EL. This makes it possible to perform alignment with high accuracy even when an alignment mark (mask mark MAM/workpiece mark WAM) is disposed at any position of the exposure surface (irradiation region IA).

In other words, the alignment microscope 4 is appropriately moved to a position at which the mask mark MAM is projected onto the reflective member 12. This makes it possible to capture the images of the mask mark MAM and the workpiece mark WAM and to align the alignment marks. As a result, it is possible to perform alignment of various masks M and workpieces W with high accuracy.

In the exposure apparatus disclosed in Japanese Patent Application Laid-open No. Hei 08-233529, a reflective member is embedded in the substantially entire surface of a workpiece stage. In other words, the reflective member is provided in the entire placement surface of the workpiece stage. The step of detecting a mask mark is performed in a state in which the workpiece is not disposed and the reflective member is exposed upward.

In the configuration in which the reflective member is embedded in the placement surface of the workpiece stage, there is a high possibility that the function of suctioning the workpiece placed on the placement surface is limited. For example, there is a high possibility that the configuration of a suction mechanism, such as the number of vacuum-suction holes and the positions thereof, is limited such that the imaging of the mask mark is not affected in the step of detecting the mask mark. Further, it is inherently difficult to form a vacuum-suction hole for vacuum suction in a reflective member formed of a mirror member or the like.

If the configuration of the suction mechanism is limited as descried above, as the size of the reflective member increases, a portion capable of suctioning the workpiece decreases. As a result, a thin workpiece such as a printed-circuit board or a wafer (e.g., workpiece having a thickness of 0.05 mm or less) fails to be vacuum-suctioned (fixed) satisfactorily, and the exposure accuracy deteriorates due to deterioration in flatness of the workpiece, alignment accuracy of the workpiece, and the like. Further, the accuracy of detecting the mask mark MAM by the alignment microscope is also lowered.

Further, in a transparent workpiece having light-transmitting property, multiple reflection of the exposure light transmitted through the workpiece during the exposure step may occur by the reflective member provided in the placement surface. In this case, unnecessary exposure or the like of the resist occurs, and thus the exposure accuracy is lowered. Further, the imaging accuracy of the workpiece mark may be lowered due to the multiple reflection in the step of detecting the workpiece mark.

Furthermore, in the configuration in which the reflective member is embedded in the placement surface of the workpiece stage, in the step of detecting the workpiece mark, the placement surface (reflective member) for the workpiece is located directly under the projection optical system, and the exposure light is to be radiated thereto. Therefore, it is impossible to replace the workpiece with another one to be disposed on the placement surface during the step of detecting the mask mark.

As a result, it is necessary to sequentially perform the step of stopping the emission of the exposure light from the light-emission unit and then placing a workpiece on the placement surface (reflective member) after the step of detecting the mask mark, resulting in low productivity.

Further, in the configuration in which the reflective member is embedded in the placement surface of the workpiece stage, the height position of the upper surface of the reflective member and the height position of the upper surface of the workpiece cannot be made equal to each other. Therefore, in the step of detecting the mask mark, it is necessary to move the workpiece stage upward by the thickness of the workpiece to adjust the focus of the image of the mask mark projected onto the reflective member. As a result, a motion stroke corresponding to the thickness of the workpiece needs to be accurate. If a positional deviation occurs when the workpiece is moved upward, the alignment accuracy of the alignment mark is lowered.

In the exposure apparatus 1 according to this embodiment, the reflective member 12 is provided at a position different from the placement surface 11 of the workpiece stage WS. The placement surface 11 is moved so as to be deviated from the irradiation region IA for the exposure light EL, and the reflective member 12 is moved to the irradiation region IA for the exposure light EL.

As a result, it is possible to form a suction mechanism capable of satisfactorily vacuum-suctioning the workpiece W onto the placement surface 11. For example, it is possible to achieve a configuration in which the vacuum-suction holes are formed evenly over the entire region of the placement surface 11, and the workpiece W is suctioned over the entire surface of the placement surface 11.

This makes it possible to sufficiently fix and hold a thin workpiece W and to prevent a decrease in flatness and alignment accuracy of the workpiece W. Further, for a transparent workpiece W, multiple reflection of the exposure light EL transmitted through the workpiece W can be prevented. As a result, for various workpieces W, high exposure accuracy can be exhibited and a workpiece-handling performance can be highly exhibited.

Further, in the exposure apparatus 1 according to this embodiment, in the step of detecting the mask mark MAM, the placement surface 11 of the workpiece stage WS is moved to a position deviated from the irradiation region IA for the exposure light EL. Therefore, the workpiece W can be replaced simultaneously with the step of detecting the mask mark MAM. As a result, the throughput can be improved and a takt time can be shortened, so that high productivity can be exhibited.

Further, in the exposure apparatus 1 according to this embodiment, as shown in FIG. 1 or the like, the reflective member 12 can be connected to the workpiece stage WS such that the height position of the upper surface S1 of the reflective member 12 and the height position of the upper surface S2 of the workpiece W are equal to each other.

Therefore, when the workpiece stage WS is moved in the horizontal direction (XY-plane direction), the reflective member 12 can be disposed in the irradiation region IA such that the height position of the surface S1 of the reflective member 12 is equal to the height position of the surface S2 of the workpiece W held by the workpiece stage WS.

As a result, for example, in the step of detecting the mask mark MAM, it is possible to eliminate the need to move the workpiece stage WS upward by the thickness of the workpiece W and possible to perform alignment of the alignment marks with high accuracy.

Further, in the step of detecting the mask mark MAM, even when the workpiece stage WS is moved along the vertical direction (Z direction) in order to make the height position of the surface S1 of the reflective member 12 coincide with the height position of the surface S2 of the workpiece W with high accuracy, a smaller amount of adjustment (amount of movement) suffices. This makes it possible to perform alignment of the alignment marks with less errors caused by the movement and with high accuracy.

As described above, in the exposure apparatus 1 according to this embodiment, in the step of detecting the mask mark MAM, the reflective member 12 is moved from the position deviated from the irradiation region IA for the exposure light EL to the irradiation region IA. This makes it possible to improve alignment accuracy of the mask M and the workpiece W and achieve high exposure accuracy.

Applying the present technology makes it possible to achieve alignment of any alignment marks in the exposure surface (irradiation region IA) while maintaining high flatness, productivity, and exposure accuracy of the workpiece W.

In this embodiment, the workpiece-stage moving mechanism 6 corresponds to one embodiment of a moving mechanism according to the present technology, which moves the reflective member from a position deviated from the irradiation region to the irradiation region in the step of detecting the mask mark.

### Second Embodiment

An exposure apparatus according to a second embodiment of the present technology will be described. Hereinafter, description of the portions having configurations and effects similar to those of the exposure apparatus 1 described in the above embodiment will be omitted or simplified.

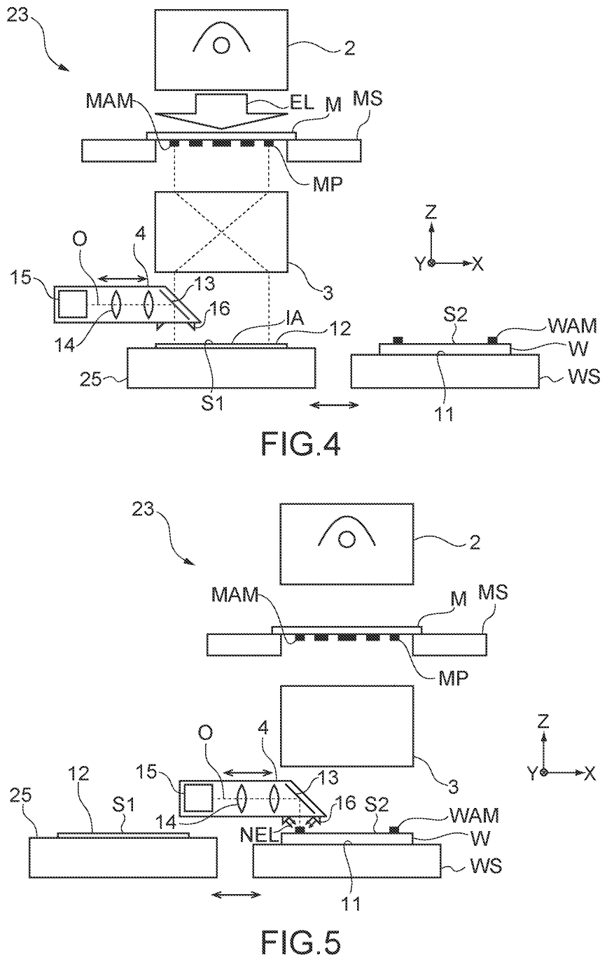

FIGS. 4 and 5 are schematic diagrams each showing a basic configuration example of the exposure apparatus according to the second embodiment. FIG. 4 is a schematic diagram showing the step of detecting a mask mark MAM. FIG. 5 is a schematic diagram showing the step of detecting a workpiece mark WAM.

In an exposure apparatus 23 according to this embodiment, a moving stage 25 that holds the reflective member 12 is configured. The reflective member 12 is fixed to and held by an upper surface portion on the upper side of the moving stage 25. A configuration and a method for fixing the reflective member 12 are not limited, and any configuration and method can be employed.

In this embodiment, the workpiece-stage moving mechanism 6 moves each of the workpiece stage WS and the moving stage 25.

The workpiece-stage moving mechanism 6 linearly moves the moving stage 25 in each of the horizontal direction (X direction), the depth direction (Y direction), and the vertical direction (Z direction). Further, the workpiece-stage moving mechanism 6 rotates the moving stage 25 with the vertical direction (Z direction) being used as a rotation-axis direction. Further, the workpiece-stage moving mechanism 6 tilts the moving stage 25 relative to the optical axis direction of the light-emission unit 2 (Z direction).

Further, in this embodiment, the workpiece-stage moving mechanism 6 can move each of the workpiece stage WS and the moving stage 25 along the same plane with the horizontal direction (XY-plane direction) being used as a surface direction.

The moving stage 25 is caused to hold the reflective member 12 such that the height position of the upper surface S1 of the reflective member 12 is equal to the height position of the upper surface S2 of the workpiece W placed on the placement surface 11. This makes it possible to move the workpiece W and the reflective member 12 in the horizontal direction (XY-plane direction) in the state in which the height position of the upper surface S1 of the reflective member 12 is equal to the height position of the upper surface S2 of the workpiece W.

For example, the workpiece stage WS and the moving stage 25 are both disposed on a surface plate (platen) and are moved in a state of being magnetically elevated by a linear motor. Such a configuration can be employed.

As shown in FIG. 4, when the workpiece-stage moving mechanism 6 is driven, the workpiece stage WS is moved such that the placement surface 11 is moved outside the irradiation region IA for the exposure light EL in the step of detecting the mask mark MAM. Further, the moving stage 25 is moved such that the reflective member 12 is disposed in the irradiation region IA for the exposure light EL. In other words, in the step of detecting the mask mark MAM, the reflective member 12 is moved from a position deviated from the irradiation region IA for the exposure light EL to the irradiation region IA.

In such a manner, in this embodiment, the workpiece-stage moving mechanism 6 moves each of the workpiece stage WS and the moving stage 25 and thus moves the reflective member 12 to the irradiation region IA for the exposure light EL.

As shown in FIG. 5, the moving stage 25 is moved such that the reflective member 12 is deviated from the irradiation region IA for the exposure light EL in the step of detecting the workpiece mark WAM. Further, the workpiece stage WS is moved such that the workpiece W placed on the placement surface 11 is disposed below the projection optical system 3.

Also in the exposure apparatus 23 according to this embodiment, it is possible to form a suction mechanism capable of satisfactorily vacuum-suctioning the workpiece W onto the placement surface 11 of the workpiece stage WS, and it is possible to exhibit high exposure accuracy for various workpieces W.

Further, the workpiece W can be replaced simultaneously with the step of detecting the mask mark MAM, and the throughput can be improved and a takt time can be shortened. As a result, high productivity can be exhibited.

Further, when each of the workpiece stage WS and the moving stage 25 is moved along the horizontal direction (XY-plane direction), the reflective member 12 can be disposed in the irradiation region IA such that the height position of the surface S1 of the reflective member 12 is equal to the height position of the surface S2 of the workpiece W held by the workpiece stage WS. This makes it possible to perform alignment of the alignment marks with high accuracy.

In this embodiment, the workpiece-stage moving mechanism 6 corresponds to one embodiment of a moving mechanism according to the present technology, which moves the reflective member from a position deviated from the irradiation region to the irradiation region in the step of detecting the mask mark. Note that a moving mechanism for moving the moving stage 25 may be configured separately from the workpiece-stage moving mechanism 6. In this case, the moving mechanism functions as one embodiment of the moving mechanism according to the present technology.

### Third Embodiment

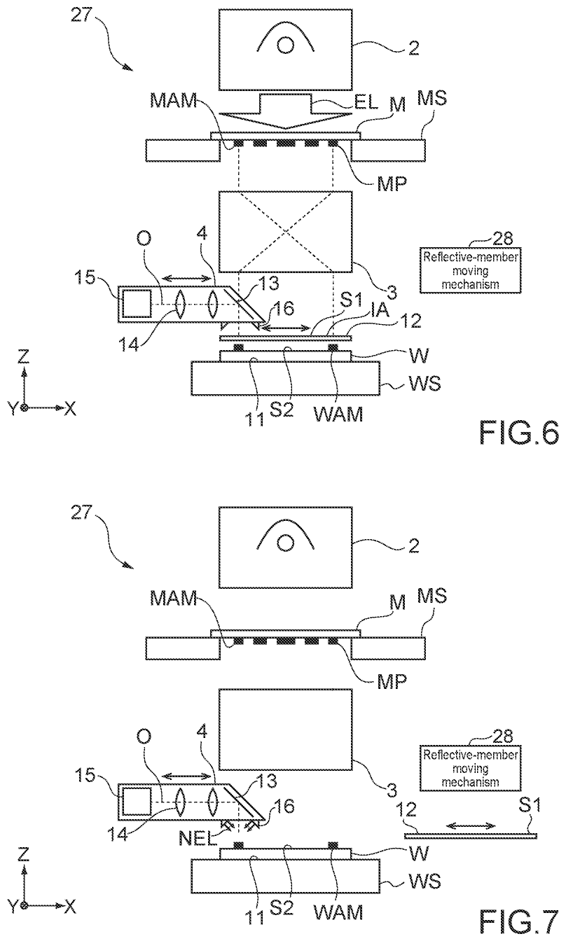

FIGS. 6 and 7 are schematic diagrams each showing a basic configuration example of an exposure apparatus according to a third embodiment. FIG. 6 is a schematic diagram showing the step of detecting a mask mark MAM. FIG. 7 is a schematic diagram showing the step of detecting a workpiece mark WAM.

In an exposure apparatus 27 according to this embodiment, a reflective-member moving mechanism 28 is configured. As shown in FIG. 6, the reflective-member moving mechanism 28 inserts the reflective member 12 between the workpiece stage WS and the alignment microscope 4 in the step of detecting the mask mark MAM, and thus moves the reflective member to the irradiation region IA for the exposure light EL.

As shown in FIG. 7, the reflective-member moving mechanism 28 moves the reflective member 12 so as to be deviated from the irradiation region IA for the exposure light EL in the step of detecting the workpiece mark WAM.

A specific configuration of the reflective-member moving mechanism 28 is not limited, and any configuration may be employed. For example, an arm mechanism that can be extended and contracted is provided to a frame member in the exposure apparatus 1, and the reflective member 12 is connected and fixed to the arm mechanism. In the step of detecting the mask mark MAM, the arm mechanism is extended, so that the reflective member 12 is disposed in the irradiation region IA for the exposure light EL. In the step of detecting the workpiece mark WAM, the arm mechanism is contracted, and thus the reflective member 12 is disposed in a position deviated from the irradiation region IA for the exposure light EL. Such a configuration may be employed.

The reflective member 12 is formed to have the size that covers the entire workpiece W, and blocks the exposure light EL applied to the workpiece W in the step of detecting the mask mark MAM. This makes it possible to prevent the workpiece W from being exposed in the step of detecting the mask mark MAM.

Also in the exposure apparatus 27 according to this embodiment, it is possible to form a suction mechanism capable of satisfactorily vacuum-suctioning the workpiece W onto the placement surface 11 of the workpiece stage WS, and it is possible to exhibit high exposure accuracy for various workpieces W.

Further, the workpiece W can be replaced simultaneously with the step of detecting the mask mark MAM, and the throughput can be improved and a takt time can be shortened. As a result, high productivity can be exhibited. Note that it may be difficult to replace the workpiece W if the position at which the reflective member 12 is inserted is close to the workpiece stage WS. In this case, the workpiece stage WS is appropriately moved, so that the workpiece W can be easily replaced.

In this embodiment, it is difficult to arrange the reflective member 12 in the irradiation region IA such that the height position of the surface S1 of the reflective member 12 is equal to the height position of the surface S2 of the workpiece W held by the workpiece stage WS.

In this embodiment, the reflective-member moving mechanism 28 corresponds to one embodiment of a moving mechanism according to the present technology, which moves the reflective member from a position deviated from the irradiation region to the irradiation region in the step of detecting the mask mark.

The exposure apparatus according to the present invention is achieved by any configuration capable of moving the reflective member from a position deviated from the irradiation region IA for the exposure light EL to the irradiation region IA in the step of detecting the mask mark MAM. This configuration makes it possible to form a suction mechanism capable of satisfactorily vacuum-suctioning the workpiece W onto the placement surface 11 of the workpiece stage WS, and to exhibit high exposure accuracy for various workpieces W.

As a matter of course, the exposure apparatuses 1, 23, and 27 according to the first to third embodiments described above are included in the exposure apparatus according to the present invention. In addition, in the exposure apparatuses 1 and 23 according to the first and second embodiments, a configuration in which the height position of the surface S1 of the reflective member 12 is not aligned with the height position of the surface S2 of the workpiece W held by the workpiece stage WS is also included in the exposure apparatus according to the present invention. In addition, any configuration may be employed.

### OTHER EMBODIMENTS

The present invention is not limited to the embodiments described above and can implement various other embodiments.

The reflective member 12 may be disposed in a partial region of the irradiation region IA for the exposure light EL. For example, if the position of the alignment mark is fixed, the reflective member 12 may be disposed in a part of the region, which corresponds to the position of the alignment mark. In this case as well, it is possible to form a suction mechanism capable of satisfactorily vacuum-suctioning the workpiece W onto the placement surface 11 of the workpiece stage WS, and it is possible to exhibit high exposure accuracy for various workpieces W.

Use of the exposure apparatus according to the present invention to perform exposure makes it possible to manufacture various substrates, on which predetermined patterns are formed, as components. For example, an electric circuit element, an optical element, a micro electro mechanical systems (MEMS), a recording element, a sensor, a mold, or the like can be manufactured as a component.

Examples of the electric circuit element include volatile or non-volatile semiconductor memories such as a dynamic random access memory (DRAM), a static random access memory (SPAM), a flash memory, and a magnetoresistive random access memory (MRAM), and semiconductor elements such as a large scale integration (LSI), a charge-coupled device (CCD), an image sensor, and a field-programmable gate array (FPGA). Examples of the mold include a mold for imprinting.

The configurations of the exposure apparatus, the control device, the alignment microscope, the moving mechanisms, the beam splitter, the optical sensor, and the like, the alignment method, the exposure method, and the like described above with reference to the figures are merely embodiments and can be discretionally modified without departing from the gist of the present invention. In other words, any other configurations, processing flows, algorithms, and the like for the purpose of practicing the present invention may be employed.

In the present disclosure, to easily understand the description, the words such as “substantially”, “approximately”, and “about” are appropriately used. Meanwhile, it does not define a clear difference between the case where those words such as “substantially”, “approximately”, and “about” are used and the case where those words are not used.

In other words, in the present disclosure, concepts defining shapes, sizes, positional relationships, states, and the like, such as “central”, “middle”, “uniform”, “equal”, “same”, “orthogonal”, “parallel”, “symmetric”, “extended”, “axial”, “columnar”, “cylindrical”, “ring-shaped”, and “annular”, are concepts including “substantially central”, “substantially middle”, “substantially uniform”, “substantially equal”, “substantially the same”, “substantially orthogonal”, “substantially parallel”, “substantially symmetric”, “substantially extended”, “substantially axial”, “substantially columnar”, “substantially cylindrical”, “substantially ring-shaped”, “substantially annular”, and the like.

For example, the states included in a predetermined range (e.g., range of ±10%) with reference to “completely central”, “completely middle”, “completely uniform”, “completely equal”, “completely the same”, “completely orthogonal”, “completely parallel”, “completely symmetric”, “completely extended”, “completely axial”, “completely columnar”, “completely cylindrical”, “completely ring-shaped”, “completely annular”, and the like are also included.

Therefore, even if the words such as “substantially”, “approximately”, and “about” are not added, the concept that is expressed by adding so-called “substantially”, “approximately”, “about”, and the like thereto can be included. To the contrary, the complete states are not necessarily excluded from the states expressed by adding “substantially”, “approximately”, “about”, and the like.

In the present disclosure, expressions using the term “than” such as “larger than A” and “smaller than A” are expressions that comprehensively include concepts that include the case of being equal to A and concepts that do not include the case of being equal to A. For example, “larger than A” is not limited to the case where it does not include “equal to A”; however, it also includes “equal to or larger than A”. Further, “smaller than A” is not limited to “less than A”; it also includes “equal to or smaller than A”.

Upon implementation of the present technology, specific settings and other settings may be appropriately employed from the concepts that are included in “larger than A” and “smaller than A” to achieve the effects described above.

At least two of the features among the features described above according to the present technology can also be combined. In other words, various features described in the respective embodiments may be combined discretionarily regardless of the embodiments. Further, the various effects described above are merely illustrative and not restrictive, and other effects may be exerted.

It should be understood by those skilled in the art that various modifications, combinations, sub-combinations and alterations may occur depending on design requirements and other factors insofar as they are within the scope of the appended claims or the equivalents thereof.

What is claimed is:

1. An exposure apparatus, comprising:
a light-emission unit that emits exposure light;
a mask stage that holds an exposure mask;
a workpiece stage that holds a workpiece;
a projection optical system that irradiates the workpiece held by the workpiece stage with the exposure light, the exposure light being emitted from the light-emission unit and passing through the exposure mask;
a reflective member that is disposed in an irradiation region for the exposure light applied from the projection optical system in a step of detecting a mask mark, the mask mark being an alignment mark of the exposure mask;
an alignment microscope that is disposed in an optical path of the exposure light applied to the mask mark and captures an image of the mask mark on a basis of reflected light that is reflected by the reflective member in the step of detecting the mask mark; and
a moving mechanism that moves the reflective member from a position deviated from the irradiation region to the irradiation region in the step of detecting the mask mark.

2. The exposure apparatus according to claim 1, wherein
the workpiece stage includes a placement surface on which the workpiece is placed, and
the moving mechanism moves the workpiece stage such that the placement surface is deviated from the irradiation region and moves the reflective member to the irradiation region in the step of detecting the mask mark.

3. The exposure apparatus according to claim 1, wherein
the moving mechanism inserts the reflective member between the workpiece stage and the alignment microscope to move the reflective member to the irradiation region in the step of detecting the mask mark.

4. The exposure apparatus according to claim 1, wherein
the reflective member is formed to have a size equal to or larger than a size of the irradiation region, and reflects a whole of the exposure light applied from the projection optical system.

5. The exposure apparatus according to claim 2, wherein
the reflective member is connected to a position different from the placement surface of the workpiece stage, and
the moving mechanism moves the workpiece stage to move the reflective member to the irradiation region.

6. The exposure apparatus according to claim 5, wherein
the reflective member is connected to the workpiece stage such that a height position of a surface of the reflective member is equal to a height position of a surface of the workpiece placed on the placement surface.

7. The exposure apparatus according to claim 2, further comprising
a moving stage that holds the reflective member, wherein
the moving mechanism moves each of the workpiece stage and the moving stage to move the reflective member to the irradiation region.

8. The exposure apparatus according to claim 7, wherein
the moving mechanism moves each of the workpiece stage and the moving stage along an identical plane, and
the reflective member is held by the moving stage such that a height position of a surface of the reflective member is equal to a height position of a surface of the workpiece placed on the placement surface.

9. The exposure apparatus according to claim 3, wherein
the reflective member is formed to have a size that covers a whole of the workpiece and blocks the exposure light applied to the workpiece in the step of detecting the mask mark.
